(19) United States
(12) Patent Application Publication
(10) Pub. No.: US 2017/0213783 A1
(43) Pub. Date: Jul. 27, 2017

(54) MULTI-CHIP SEMICONDUCTOR POWER PACKAGE

(71) Applicant: Infineon Technologies AG, Neubiberg (DE)

(72) Inventors: Andreas Meiser, Sauerlach (DE); Matthias Grewe, Putzbrunn (DE); Stefan Macheiner, Kissing (DE)

(73) Assignee: Infineon Technologies AG, Neubiberg (DE)

(21) Appl. No.: 15/414,815

(22) Filed: Jan. 25, 2017

(30) Foreign Application Priority Data
Jan. 27, 2016 (DE) 10 2016 101 433.8

(51) Int. Cl. H01L 23/495; H01L 23/00

(52) U.S. Cl. CPC H01L 23/49562; H01L 24/40; H01L 23/49593; H01L 2924/1304

(57) ABSTRACT

A semiconductor package is disclosed. The semiconductor package includes an electrically conducting carrier having a mounting surface, a first level first semiconductor power device having a first load electrode mounted over the mounting surface of the electrically conducting carrier and having a second load electrode opposite the first electrode. The package further includes a first level second semiconductor power device. A first connection element has a first surface connected to the second load electrode of the first level first semiconductor power device. A second connection element has a first surface connected to the second load electrode of the first level second semiconductor power device. The package includes a second level first semiconductor power device and a second level second semiconductor power device.

### CROSS-REFERENCE TO RELATED APPLICATION

This Utility Patent Application claims priority to German Patent Application No. 10 2016 101 433.8, filed Jan. 27, 2016; which is incorporated herein by reference.

### TECHNICAL FIELD

This invention relates to the technique of packaging, and in particular to the technique of packaging multiple semiconductor chips in a stacked configuration for power applications.

### BACKGROUND

Semiconductor package manufacturers are constantly striving to increase the performance of their products, while decreasing their cost of manufacture. A cost intensive area in the manufacture of semiconductor devices is packaging the semiconductor chips. The semiconductor chips may be mounted on electrically conductive carriers, such as, e.g., leadframes, and electrical connections to chip electrodes and external contacts of the package have to be produced. In particular, packages having low cost electrical connections and reduced electromagnetic stray radiation are desirable.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1A is a perspective view of a source/emitter-down semiconductor power chip showing the front side of the semiconductor power chip.

FIG. 1B is a perspective view of the source/emitter-down semiconductor power chip of FIG. 1A showing the rear side of the semiconductor power chip.

FIG. 2A is a perspective view of a drain/collector-down semiconductor power chip showing the front side of the semiconductor power chip.

FIG. 2B is a perspective view of the drain/collector-down semiconductor power chip of FIG. 2A showing the rear side of the semiconductor power chip.

FIG. 3A schematically illustrates a top view of a semiconductor package that includes a multi-level semiconductor chip arrangement using source/emitter-down semiconductor power chips as illustrated in FIGS. 1A-B.

FIG. 3B schematically illustrates a side view of the semiconductor package of FIG. 3A as seen from view V1 in FIG. 3A.

FIG. 3C schematically illustrates a sectional view of the semiconductor package of FIG. 3A along line A-A in FIG. 3A.

FIG. 4 is a circuit diagram of a 2-phase bridge as, e.g., illustrated in FIGS. 3A-C.

FIG. 5A schematically illustrates a top view of a semiconductor package that includes a multi-level semiconductor chip arrangement using source/emitter-down semiconductor power chips as illustrated in FIGS. 1A-B.

FIG. 5B schematically illustrates a side view of the semiconductor package of FIG. 5A as seen from view V1 in FIG. 5A.

FIG. 5C schematically illustrates a sectional view of the semiconductor package of FIG. 5A along line A-A in FIG. 5A.

FIG. 6 is a circuit diagram of a 3-phase bridge as, e.g., illustrated in FIGS. 5A-C.

FIG. 7A schematically illustrates a top view of a semiconductor package that includes a multi-level semiconductor chip arrangement using drain/collector-down semiconductor power chips as illustrated in FIGS. 2A-B.

FIG. 7B schematically illustrates a side view of the semiconductor package of FIG. 7A as seen from view V1 in FIG. 7A.

FIG. 7C schematically illustrates a side view of the semiconductor package of FIG. 7A as seen from view V2 in FIG. 7A.

FIG. 8 schematically illustrates a top view of a semiconductor package that includes a multi-level semiconductor chip arrangement using source/emitter-down semiconductor power chips as illustrated in FIGS. 1A-B and a control semiconductor chip.

### DETAILED DESCRIPTION OF ILLUSTRATIVE EMBODIMENTS

In the following detailed description, reference is made to the accompanying drawings, which form a part thereof, and in which is shown by way of illustration specific embodiments in which the invention may be practiced. In this regard, directional terminology, such as “top”, “bottom”, “front”, “back”, “upper”, “lower”, etc., is used with reference to the orientation of the Figure(s) being described. Because parts used in the various embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

As employed in this specification, the terms “coupled” and/or “connected” are not meant to mean in general that elements must be directly coupled or connected together. Intervening elements may be provided between the “coupled” or “connected” elements. However, although not restricted to that meaning, the terms “coupled” and/or “connected” may also be understood to optionally disclose an aspect in which the elements are directly coupled or connected together without intervening elements provided between the “coupled” or “connected” elements.

Semiconductor power packages containing four or more power semiconductor devices are described herein. The power semiconductor devices are arranged in at least two levels x (lower level) and y (upper level). At least two semiconductor power devices are arranged in the lower level x.

All semiconductor power devices in the package or at least a part thereof may have a vertical structure, that is to say that the semiconductor devices may be fabricated in such a way that electric currents can flow in a direction perpendicular to the main surfaces of the semiconductor chip in which the semiconductor power device(s) is (are) implemented. A semiconductor power device having a vertical structure is implemented in a semiconductor chip having electrodes on its two main surfaces, that is to say on its top side and bottom side. A semiconductor chip may contain one or more semiconductor devices, i.e. one or more semiconductor devices may be monolithically integrated in one semiconductor chip.

Vertical power semiconductor devices may, for example, be configured as MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors) or power bipolar transistors. By way of example, the source (emitter) electrode of a power MOSFET (IGBT) may be arranged on one main surface, while the drain (collector) electrode of the power MOSFET (IGBT) may be arranged on the other main surface. The gate electrode of the MOSFET (IGBT) may be arranged either on the main surface on which the source (emitter) of the MOSFET (IGBT) is arranged or on the main surface on which the drain (collector) of the MOSFET (IGBT) is arranged.

The power semiconductor devices referred to herein may be manufactured from specific semiconductor material such as, for example, Si, SiC, SiGe, GaAs, GaN, AlGaN, InGaAs, InAlAs, etc, and, furthermore, may contain inorganic and/or organic materials that are not semiconductors. The power semiconductor devices arranged in the package may be of different types and may be manufactured by different technologies.

Two or more semiconductor power devices (which may be monolithically integrated in one or more semiconductor chips) are mounted over and are electrically connected to an electrically conducting carrier of the package. In one embodiment, the electrically conducting carrier may be a continuous metal plate or sheet such as, e.g., a die pad of a leadframe. The metal plate or sheet may be made of any metal or metal alloy, e.g. copper or copper alloy. In other embodiments the electrically conducting carrier may, e.g., comprise a plate of ceramics coated with metal layer(s). By way of example, such electrically conducting carrier may be a metal bonded ceramics substrate, e.g. a DCB (direct copper bonded) ceramics substrate.

Furthermore, the semiconductor packages described herein may include one or more logic integrated circuit to control the power semiconductor devices. The logic integrated circuit may include one or more driver circuits to drive one or more of the power semiconductor devices. The logic integrated circuit may, e.g., be a microcontroller including, e.g., memory circuits, level shifters, etc.

The electrically conducting carrier and/or the semiconductor power chips (in which the semiconductor power devices are implemented) may at least partly be surrounded or embedded in at least one electrically insulating material. The electrically insulating material forms an encapsulation body of the package. The encapsulation body may comprise or be made of a mold material. Various techniques may be employed to form the encapsulation body of the mold material, for example compression molding, injection molding, powder molding or liquid molding. The encapsulation body may form part of the periphery of the package, i.e. may at least partly define the shape of the semiconductor package.

The electrically insulating material may comprise or be made of a thermoset material or a thermoplastic material. A thermoset material may e.g. be made on the basis of an epoxy resin. A thermoplastic material may e.g. comprise one or more materials of the group of polyetherimide (PEI), polyether-sulfone (PES) polyphenylene-sulfide (PPS) or polyamide-imide (PAI). Thermoplastic materials melt by application of pressure and heat during molding or lamination and (reversibly) harden upon cooling and pressure release.

The electrically insulating material forming the encapsulation body may comprise or be made of a polymer material. The electrically insulating material may comprise at least one of a filled or unfilled mold material, a filled or unfilled thermoplastic material, a filled or unfilled thermoset material, a filled or unfilled laminate, a fiber-reinforced laminate, a fiber-reinforced polymer laminate, and a fiber-reinforced polymer laminate with filler particles.

A variety of different types of power packages may be designed by the techniques described herein. For instance, a power package disclosed herein may comprise two half-bridge circuits each including a high side power transistor and a low side power transistor. Further, by way of example, a power package disclosed herein may comprise three or even more half-bridge circuits each including a high side power transistor and a low side power transistor.

A power package as described herein may, e.g., be configured as a multi-phase bridge. Such multi-phase bridge may be configured to be used in power supplies, e.g. power supplies for electrical motors such as, e.g. brushless DC (BLDC) motors. Multi-phase bridges as described herein may also be used as rectifiers or power converters, e.g. DC-DC power converters or AC-DC power converters.

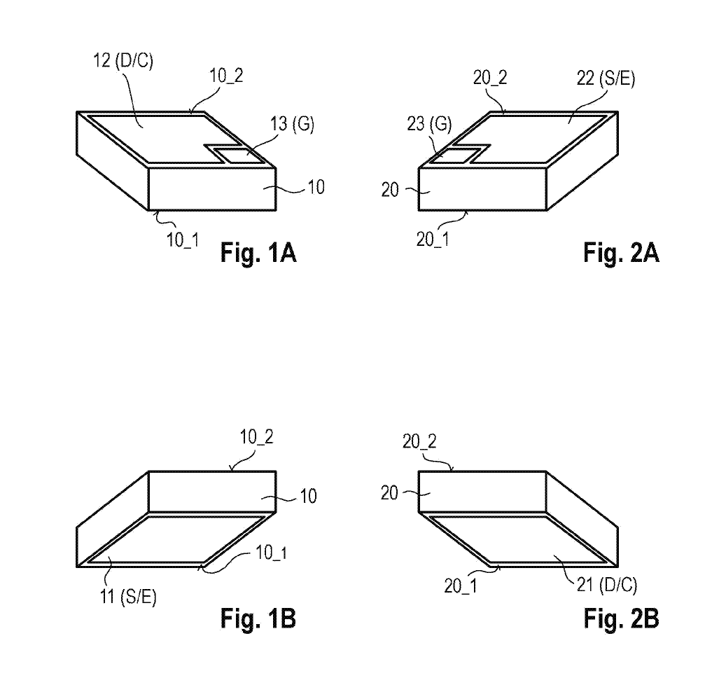

FIG. 1 illustrates a source/emitter-down semiconductor power chip 10. The source/emitter-down semiconductor power chip 10 has a first surface 10_1 and a second surface 10_2 opposite the first surface 10_1. The first surface 10_1 represents the rear side of the source/emitter-down semiconductor power chip 10 and the second surface 10_2 represents the front side of the source/emitter-down semiconductor power chip 10.

A source or emitter (S/E) electrode 11 is arranged on the first surface 10_1 (rear side) of the source/emitter-down semiconductor power chip 10. A drain or collector (D/C) electrode 12 and a gate (G) electrode 13 are arranged on the second surface 10_2 (front side) of the source/emitter-down semiconductor power chip 10. The gate electrode 13 serves to control an electric current between the S/E electrode 11 and the D/C electrode 12. The gate electrode 13 may be used to switch the electrical current between the S/E electrode 11 and the D/C electrode 12 ON or OFF or to adjust the electrical current between the S/E electrode 11 and the D/C electrode 12 to an adjustable value between substantially 0 A (Ampere) and a maximum current that is established if the source/emitter-down semiconductor power chip 10 is turned ON.

The source/emitter-down semiconductor power chip 10 may include a number N of semiconductor power devices, with N being an integer equal to or greater than 1. In this case, the source/emitter-down semiconductor power chip 10 may have one common S/E electrode 11 shared by all semiconductor power devices, N D/C electrodes 12 (i.e. for each semiconductor power device one D/C electrode) and N gate electrodes 13 (i.e. for each semiconductor power device one gate electrode 13).

FIG. 2 illustrates a drain/collector-down semiconductor power chip 20. The drain/collector-down semiconductor power chip 20 has a first surface 20_1 and a second surface 20_2 opposite the first surface 20_1. The first surface 20_1 represents the rear side of the drain/collector-down semiconductor power chip 20 and the second surface 20_2 represents the front side of the drain/collector-down semiconductor power chip 20.

A drain or collector (D/C) electrode 21 is arranged on the first surface 20_1 (rear side) of the drain/collector-down semiconductor power chip 20. A source or emitter (S/E) electrode 22 and a gate (G) electrode 23 are arranged on the second surface 20_2 (front side) of the drain/collector-down semiconductor power chip 20. The gate electrode 23 serves to control an electric current between the D/C electrode 21 and the S/E electrode 22. The gate electrode 23 may be used to switch the electrical current between the D/C electrode 21 and the S/E electrode 22 ON or OFF or to adjust the electrical current between the D/C electrode 21 and the S/E electrode 22 to an adjustable value between substantially 0 A and a maximum current that is established if the drain/collector-down semiconductor power chip 20 is turned ON.

Similar to the source/emitter-down semiconductor power chip 10 of FIGS. 1A-B, the drain/collector-down semiconductor power chip 20 may also include a number N of semiconductor power devices. In this case, the drain/collector-down semiconductor power chip 20 may have one common D/C electrode 21 shared by all semiconductor power devices, N S/E electrodes 22 (i.e. for each semiconductor power device one S/E electrode) and N gate electrodes 23 (i.e. for each semiconductor power device one gate electrode 23).

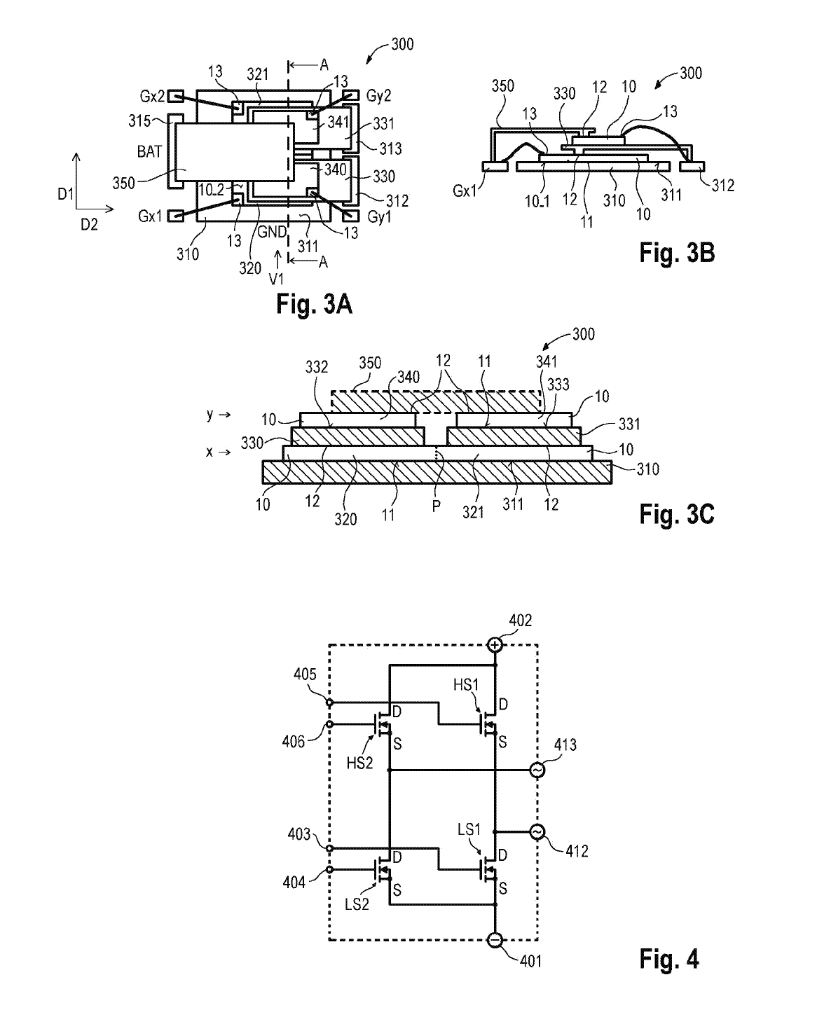

FIGS. 3A-C illustrate a semiconductor power package 300 in accordance with embodiments described herein. The semiconductor power package 300 comprises an electrically conducting carrier 310. The electrically conducting carrier 310 may be a metal carrier, e.g. a leadframe. In other examples the electrically conducting carrier 310 may be a ceramic plate coated with a metal layer on its top surface or on both surfaces. The top surface of the electrically conducting carrier 310 may form a mounting surface 311 of the electrically conducting carrier 310.

In the following, semiconductor power devices placed on the mounting surface 311 will be referred to as level x (or first level) semiconductor power devices. As may be seen in FIGS. 3A-C, a level x first semiconductor power device 320 and a level x second semiconductor power device 321 are mounted over the mounting surface 311 of the electrically conducting carrier 310.

The level x first and second semiconductor power devices 320, 321 may each be formed by a source/emitter-down semiconductor power chip 10 as illustrated in FIGS. 1A-B. In this case, two source/emitter-down semiconductor power chips 10 may be arranged next to each other. Each source/emitter-down semiconductor power chip 10 has its first surface 10_1 containing the S/E electrode 11 mounted on the mounting surface 311. In another example, the level x first semiconductor power device 320 and the level x second semiconductor power device 321 are both monolithically integrated in one source/emitter-down semiconductor power chip 10. In this case, the single source/emitter-down semiconductor power chip 10 may be provided with a common S/E electrode 11 at its first surface 10_1 and with two D/C electrodes 12 and two gate electrodes 13, i.e. one D/C electrode 12 and one gate electrode 13 for each of the two level x first and second semiconductor power devices 320, 321.

In general, if N level x semiconductor power devices 320, 321, . . . are mounted on the mounting surface 311 of the electrically conducting carrier 310, the number of source/emitter-down semiconductor power chips 10 in which the level x semiconductor power devices are implemented may range from 1 to N. In FIG. 3C the option of having one or two source/emitter-down semiconductor power chips 10 for is indicated by a dotted partition line P.

A first connection clip 330 is mounted over the D/C electrode 12 of the level x first semiconductor power device 320 and a second connection clip 331 is mounted over the D/C electrode 12 of the level x second semiconductor power device 321. Each of the first and second connector clips 330, 331 is electrically conducting, e.g. made of a metal material. Each of the first and second connector clips 330, 331 is electrically connected to the respective D/C electrode 12 of the respective level x first or second semiconductor power device 320 and 321, respectively.

The first connection clip 330 has a mounting surface 332 opposite the clip surface connected to the D/C electrode 12 of the level x first semiconductor power device 320. Similarly, the second connection clip 331 has a mounting surface 333 opposite the surface connected to the D/C electrode 12 of the level x second semiconductor power device 321.

As illustrated in FIG. 3B, the first connection clip 330 and/or the second connection clip 331 may have a first part extending substantially parallel to the main surfaces 10_1, 10_2 of the source/emitter-down semiconductor power chip 10 and may have a bent part leading down to an external terminal 312 and 313, respectively, of the semiconductor power package 300. The external terminals 312, 313 may be located in the same plane as the electrically conducting carrier 310. By way of example, the electrically conducting carrier 310 may form a chip pad of a leadframe and the external terminals 312, 313 may form terminal pads (or terminal leads) of the same leadframe.

The mounting surfaces 332, 333 of the first connection clip 330 and the second connection clip 331, respectively, may define a second level y for placing semiconductor power chips. More specifically, a level y first semiconductor power device 340 may be mounted over the mounting surface 332 of the first connection clip 330 and a level y second semiconductor power device 341 may be mounted over the mounting surface 333 of the second connection clip 331.

The level y first semiconductor power device 340 and the level y second semiconductor power device 341 may each be implemented in a source/emitter-down semiconductor power chip 10 as explained in conjunction with FIGS. 1A-B. Hence, the S/E electrode 11 of the level y first semiconductor power device 340 is electrically connected to the mounting surface 332 of the first connection clip 330 and the S/E electrode 11 of the level y second semiconductor power device 341 is electrically connected to the mounting surface 333 of the second connection clip 331.

The D/C electrodes 12 of the level y first and second semiconductor power devices 340, 341 may be electrically connected to each other by a connection element 350. The connection element 350 may, e.g., be a connection clip as illustrated in FIGS. 3A-C.

More specifically, the connection element 350 may have the shape of a plate extending in a parallel direction over the second surfaces 10_2 of the source/emitter-down semiconductor power chips 10 implementing the level y first semiconductor power device 340 and the level y second semiconductor power device 341, respectively. The plate may have a bent part configured to connect the connection element 350 to an external terminal 315 of the semiconductor package 300. Similar to the external terminals 312, 313 the external terminal 315 may, e.g., be formed of a lead pad or a lead of a leadframe which also provides for the electrically conducting carrier 310. It is to be noted that the connection element 350 may also be formed by implementations other than a connection clip, e.g. by an electrically conducting ribbon or by wire bonds.

As illustrated in FIGS. 3A-B, the semiconductor package 300 may comprise further external terminals Gx1, Gx2, Gy1 and Gy2. External terminal Gx1 may be electrically connected to gate electrode 13 of the level x first semiconductor power device 320, external terminal Gx2 may be electrically connected to the level x second semiconductor power device 321, external terminal Gy1 may be electrically connected to gate electrode 13 of the level y first semiconductor power device 340 and external terminal Gy2 may be electrically connected to the level y second semiconductor power device 341. All aforementioned connections from the gate electrodes 13 to the external terminals Gx1, Gx2, Gy1, Gy2 may be made, e.g., by wire bonds. Alternatively, it is also possible to use (gate) connection clips for forming these connections. In this case, it is possible that the entire electrical interconnect of the package 300 is established by connection clips (this may also apply to any package disclosed herein).

Further, the external terminals Gx1, Gx2, Gy1, Gy2 may be located in the same plane as the electrically conducting carrier 310 and/or the external terminals 312, 313, 315. By way of example, the external terminals Gx1, Gx2, Gy1, Gy2 may be formed by pads or leads of a leadframe providing also for the electrically conducting carrier (as a chip pad of the leadframe) and the external terminals 312, 313, 315 (as leads or pads of the leadframe).

Referring to FIG. 3A, the level y first semiconductor power device 340 and the level y second semiconductor power device 341 may be arranged in a row along dimension D1. The connection element 350 extends from one end (where it is connected to the D/C electrodes 12 of the level y first and second semiconductor power devices 340, 341) to another end, where it is connected to the external terminal 315, along a dimension D2 perpendicular to dimension D1. The first connection clip 330 and the second connection clip 331 may also extend along dimension D2, however, in opposite direction than the connection element 350. As such, the external terminals 312 and 313 may be arranged at a peripheral side of the package 300 opposite the peripheral side where the external terminal 315 is arranged.

Still referring to FIG. 3A, the external terminals Gx1 and Gx2 (connecting to gate electrodes 13 on level x) may be arranged at the same peripheral side of the package 300 as the external terminal 315. Similarly, the external terminals Gy1, Gy2 (connecting to gate electrodes 13 on level y) may be arranged at the same peripheral side of the package 300 as the external terminals 312, 313. That way, only two peripheral sides of the semiconductor power package 300 are equipped with external terminals, while the remaining two sides may void of external terminals. Owing to the routing of the package interconnect, as shown in FIGS. 3A-C, the semiconductor package may be very compact, i.e. small in dimensions D1 and D2. Concurrently, a great part of the footprint of the semiconductor package 300 (e.g. equal to or more than 50%, 60%, 70%, 80%, or 90% of the footprint area) may be formed by the electrically conducting carrier 310 which allows excellent thermal dissipation from the package 300 to an external mounting platform (not shown) such as, e.g., a PCB (printed circuit board) or a heat sink.

Semiconductor power package 300 may form a 2-phase bridge. An example of a circuit diagram of a 2-phase bridge is illustrated in FIG. 4. The 2-phase bridge comprises two half-bridges. The first half-bridge comprises low side switch LS1 and high side switch HS1 connected in series between a negative supply voltage (e.g. ground: GND) 401 and a positive supply voltage (e.g. battery: BAT) 402. The second half-bridge comprises low side switch LS2 and high side switch HS2 connected in series between the negative supply voltage 401 and the positive supply voltage 402. The control electrodes (e.g. gate electrodes) of the low side switches LS1 and LS2 are connected to nodes 403 and 404, respectively. The control electrodes (e.g. gate electrodes) of the high side switches HS1 and HS2 are connected to nodes 405 and 406, respectively. The connection between low side switch LS1 and high side switch HS1 of the first half-bridge is connected to node 412. The connection between low side switch LS2 and high side switch HS2 of the second half-bridge is connected to node 413.

In the example illustrated in FIG. 4, the low side switches LS1, LS2 and the high side switches HS1, HS2 are implemented, e.g., by MOSFETs. In this case, the node 412 is connected to the drain of LS1 and the source of HS1, and the node 413 is connected to the drain of LS2 and the source of HS2. However, it is also possible that the low side switches LS1, LS2 and the high side switches HS1 and HS2 are implemented, e.g., by IGBTs. In this case, the circuit diagram would be similar to the circuit diagram of FIG. 4 except that IGBTs replace the MOSFETs. Then, node 412 would be connected to the collector of LS1 and the emitter of HS1, and node 413 would be connected to the collector of LS2 and the emitter of HS2.

As may be understood by comparing the circuit diagram of FIG. 4 with the semiconductor power package 300 illustrated in FIGS. 3A-C, the electrically conducting carrier 310 corresponds to node 401, the level x first and second semiconductor power devices 320, 321 correspond to LS1 and LS2, respectively, the first connection clip 330 and the second connection clip 331 correspond to node 412 and node 413, respectively, the level y first and second semiconductor power devices 340, 341 correspond to HS1 and HS2, respectively, the external terminals Gx1, Gx2, Gy1, Gy2 correspond to node 403, node 404, node 405 and node 406, respectively, and the external terminal 315 corresponds to node 402.

The external terminals 312, 313 (corresponding to nodes 412, 413 of the circuit diagram in FIG. 4) represent the output terminals of the semiconductor power package 300. By way of example, external terminal 312 may be electrically connected to a first phase input and external terminal 313 may be electrically connected to a second phase input of an external device (e.g. motor) which is energized by the semiconductor power package 300.

It is to be noted that the electrical connections between the electrically conducting carrier 310, the level x first and second semiconductor power devices 320, 321, the first and second connection clips 330, 331, the level y first and second semiconductor power devices 340, 341, and the connection element 350 may be formed by soldering, e.g. soft soldering, hard soldering, diffusion soldering, or by any other suitable connecting methods such as sintering, gluing by an electrically conducting adhesive, etc.

Further, it is to be noted that the semiconductor power package 300 may be provided with an encapsulant providing for the body of the semiconductor power package 300 and enclosing the arrangement shown in FIGS. 3A-C. However, the bottom surface of the electrically conducting carrier 310 (i.e. the surface opposite the mounting surface 311 thereof) and the bottom surfaces of the external terminals 312, 313, 314, Gx1, Gx2, Gy1, Gy2 or leads forming these external terminals may be exposed at or protrude out of the encapsulant.

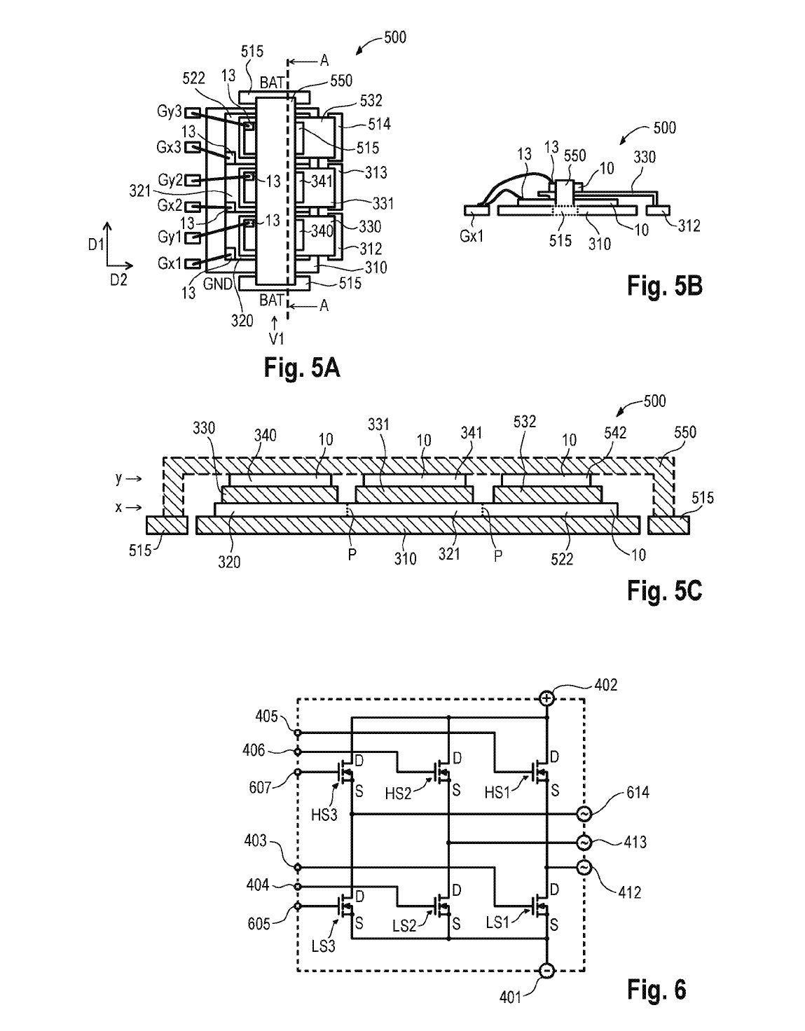

FIGS. 5A-5C illustrate a semiconductor power package 500. The semiconductor power package 500 is an example of a 3-phase bridge, which is composed of three half-bridges rather than two half-bridges as exemplified by semiconductor power package 300. Except this and other differences, which will be explained in more detail further below, the semiconductor power package 500 is similar to semiconductor power package 300, and reference is made to the above description in order to avoid reiteration.

The semiconductor power package 500 additionally comprises a level x third semiconductor power device 522, which is implemented either in the same source/emitter-down semiconductor power chip 10 as the level x first and second semiconductor power devices 320, 321 or in an individual source/emitter-down semiconductor power chip 10. The level x first, second and third semiconductor power devices 320, 321, 522 may be arranged in a row extending along dimension D1.

The level x third semiconductor power device 522 is connected to a third connection clip 532 mounted over the second surface 10_2 of the corresponding source/emitter-down semiconductor power chip 10 and connected to the D/C electrode 12 thereof. The first, second and third connection clips 330, 331 and 532 are also arranged in a row extending along dimension D1.

A level y third semiconductor power device 542 is mounted on the third connection clip 532. The level y third semiconductor power device 542 may be implemented by a source/emitter-down semiconductor power chip 10, see FIGS. 1A-B.

As apparent in FIGS. 5A-B, the gate electrodes 13 of the level y first, second and third semiconductor power devices 340, 341, 542 are located at the left side of the corresponding chips, i.e. near to the gate electrodes 13 of the level x first, second and third semiconductor power devices 320, 321, 532. That way, the external terminals Gx1, Gy1, Gx2, Gy2, Gx3 (connected to the gate electrode 13 of the level x third semiconductor power device 532) and Gy3 (connected to the gate electrode 13 of the level y third semiconductor power device 542) may be arranged in a row extending in dimension D1 along a peripheral side of the semiconductor power package 500. That is, all external terminals connecting to gate electrodes 13 may be arranged along one peripheral side of the semiconductor power package 500.

A connection element 550 is mounted over and electrically connected to the D/C electrodes 12 of the level y first, second and third semiconductor power devices 340, 341, 542. The connection element 550 may be similar to connection element 350 (e.g. may be formed by a connection clip) and reference is made to the description above. However, in this example, the connection element 550 spans the semiconductor power package 500 in dimension D1 from one peripheral side of the semiconductor package to the opposite peripheral side thereof. Thus, the connection element 550 may extend along dimension D1 rather than along dimension D2 as shown in the example of semiconductor power package 300.

Similar to semiconductor power package 300 the output external terminals 312, 313 and an additional output external terminal 514 are arranged along the right peripheral side of the package body. In this example no external gate terminals are arranged along this side of the semiconductor power package 500. Thus, the semiconductor power package 500 may have external output terminals 312, 313, 514 exclusively arranged at the right peripheral side of the package body (extending along dimension D1), gate external terminals Gx1, Gy1, Gx2, Gy2, Gx3, Gy3 exclusively arranged at the opposite peripheral side of the package body and external terminals 315 arranged along one or two of the peripheral package sides running along dimension D2.

In the semiconductor power package 500 the high voltage external terminals (positive supply voltage at external terminal(s) 315, output phases at external terminals 312, 313, 514) are spatially separated from the low voltage external terminals Gx1, Gy1, Gx2, Gy2, Gx3, Gy3. This facilitates to provide for the required dielectric strength of the semiconductor power package 500 and may further be advantageous in view of PCB layout.

According to FIG. 6, showing an example circuit diagram of a 3-phase bridge, a third half-bridge is implemented by low side switch LS3 and high side switch HS3. The phase output connected to the drain of low side switch LS3 and the source of high side switch HS3 is connected to output node 614. The gate of the low side switch LS3 is connected to the node 605 and the gate of the high side switch HS3 is connected to the node 607. Regarding the semiconductor power package 500 of FIGS. 5A-C, the node 605 corresponds to external terminal Gx3, the node 607 corresponds to external terminal Gy3 and the output node 614 corresponds to external terminal 514. Again, as mentioned previously in conjunction with FIG. 4, MOSFETs of FIG. 6 may be replaced by IGBTs, if desired.

In the examples of semiconductor power packages 300, 500 as illustrated in FIGS. 3A-C and 5A-C, many of the different features are interchangeable in a sense that one specific feature of semiconductor power package 500 may be replaced by the corresponding specific (different) feature of power package 300, and vice versa. By way of example, the connection element 550 of semiconductor power package 500 extending along dimension D1 may replace the connection element 350 used by way of example in semiconductor power package 300. Moreover, the external terminals Gy1 and Gy2 of semiconductor power package 300 may be designed to be arranged at the same peripheral side and adjacent to external terminals Gx1 and Gx2 similar to the arrangement of the corresponding external terminals in semiconductor power package 500. In this case, the level y first and second semiconductor power devices 340, 341 of power package 300 may be oriented the same way as in power package 500. Briefly put, the semiconductor power package 300 may be designed partly or completely identical to power package 500 in view of its footprint and setup (except that the third half-bridge does not exist). Vice versa, it is possible that semiconductor power package 500 is designed in line with corresponding features of semiconductor power package 300 (and by adding the components required for the third half-bridge).

Further, the arrangements and concepts described by way of example for semiconductor power packages 300 and 500 may be extended to multi-phase bridges having more than three half-bridges. The extension of semiconductor power packages 300 and 500 (or “hybride” power packages using some of the features of semiconductor power package 300 and some of the features of semiconductor power package 500) to N-phase bridges is evident, and reiteration of the above disclosure is omitted for the sake of brevity.

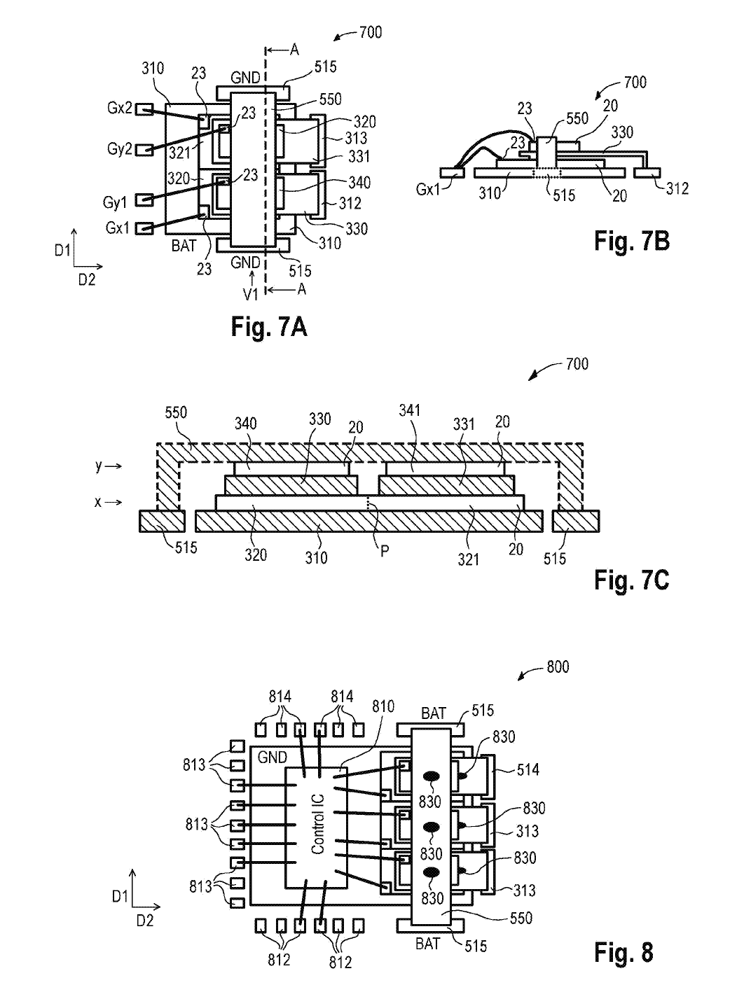

FIGS. 7A-C illustrate a semiconductor power package 700. Semiconductor power package 700 is similar to semiconductor power package 300, and reference is made to the description above in order to avoid reiteration. However, in semiconductor power package 700 a part or all of the level x first and second semiconductor power devices 320, 321 and a part or all of the level y first or second semiconductor power devices 340, 341 are implemented by drain/collector-down semiconductor power chips 20 as illustrated in FIGS. 2A-B. As such, the D/C electrode 21 is now located at the (bottom) rear side 20_1 of the semiconductor power chip 20 and the S/E electrode 22 and the gate electrode 23 are now located at the (top) front side 20_2 of the semiconductor power chip 20. This is the common or “classical” design of semiconductor power chips as known in the art.

Further, semiconductor power package 700 illustrates an example in which a connection element 550 extends along dimension D1 similar to the connection element 550 of semiconductor power package 500. Further, the spatial separation of the low voltage external terminals Gx1, Gy1, Gx2, Gy2 and the high voltage external terminals 312, 313 and the positive supply voltage at electrically conducting carrier 310 is similar to semiconductor power package 500, and reference is made to the description above in order to avoid reiteration.

As drain/collector-down semiconductor power chips 20 are used in the semiconductor package 700, the correspondence of the circuit diagram of FIG. 4 to the components of the semiconductor power package 700 is as follows: The low side switch LS1 and the high side switch HS1 of the first half-bridge correspond to the level y first semiconductor power device 340 and the level x first semiconductor power device 320, respectively. The low side switch LS2 and the high side switch HS2 of the second half-bridge correspond to the level y second semiconductor power device 341 and the level x second semiconductor power device 321, respectively. The nodes 412 and 413 correspond to the external terminals 312 and 313, respectively. The nodes 403, 404, 405, 406 correspond to the external (gate) terminals Gy1, Gy2, Gx1 and Gx2, respectively. The supply voltage nodes 401 (negative supply voltage) and 402 (positive supply voltage) correspond to external terminal(s) 515 and the electrically conducting carrier 310, respectively.

It is to be noted that the semiconductor power package 700 may alternatively be formed in accordance with the setup of semiconductor power package 300, i.e. having a connection element 350 extending along dimension D2 and having the external terminals Gx1, Gy1, Gx2, Gy2, 312, 313, 315 arranged along the peripheral sides of the package body in accordance with the semiconductor power package 300.

FIG. 8 illustrates a semiconductor power package 800. Semiconductor power package 800 is similar to semiconductor power package 500, and reference is made to the disclosure above in order to avoid reiteration. In contrast to semiconductor power package 500 the gate electrodes 13 of the level x first, second and third semiconductor power devices 320, 321, 522 and of the level y first, second and third semiconductor power devices 340, 341, 542 are at least partly connected to a control integrated circuit (control IC) 810 rather than to external terminals Gx1, Gy1, Gx2, Gy2, Gx3, Gy3 of the semiconductor power package 800. The control IC 810 may be mounted on the electrically conducting carrier 310. The control IC 810 may be partly or fully embedded in the encapsulant (not shown) forming the body of the semiconductor power package 800. In the example illustrated in FIG. 8, the electrically conducting carrier 310 is connected to the negative supply voltage 401, e.g. ground (GND). Thus, the control IC 810 may be bonded directly onto the electrically conducting carrier 310 without any insulating layer needed in between.

The control IC 810 may comprise a number of gate drivers, e.g. 6 gate drivers in the example shown in FIG. 8. The control IC 810 may further include logic to control the gate drivers. The control IC 810 may further include input pads which are electrically connected to external terminals 812, 813, 814 of the semiconductor power package 800. The external terminals 812, 813, 814 may be arranged at peripheral side(s) of the semiconductor power package 800 along dimension D1 and/or dimension D2. The external terminals 812, 813, 814 may be formed by terminal pads or leads of the aforementioned leadframe, which also provides for the electrically conducting carrier 310 (chip pad) and the external terminals 312, 313, 514 and 515. The external terminals 812, 813, 814 connected via, e.g., wire bonds to the input pads of the control IC 810 may receive an external input signal such as, e.g., a PWM (pulse width modulated) signal.

It is to be noted that the semiconductor power packages 300, 500 and 700 may also be equipped with a control IC 810 similar to semiconductor power package 800. However, if drain/collector-down semiconductor power chips 20 are used instead of source/emitter-down semiconductor power chips 10, the control IC 810 is electrically insulated from the electrically conducting carrier 310 by an insulating layer (not shown) extending between the electrically conducting carrier and the control IC 810.

Further, in all embodiments disclosed herein the first, second and third connection clips 330, 331, 532 and/or the connection elements 350, 550 may be equipped with through holes 830. The through holes 830 may serve as venting holes during the manufacturing process of the semiconductor power package 300, 500, 700, 800, e.g. during a solder reflow process for connecting the semiconductor chips 10 or 20 to the connection clips 330, 331, 532 and/or the connection elements 350, 550. Further, the through-holes 830 of the first, second and third connection clips 330, 331, 532 may provide for a solder exchange between the upper surface (mounting surface 332, 333) and the bottom surface of the connection clips 330, 331, 532.

Still further, in all embodiments disclosed herein electrical connections (e.g. bond wires) may be provided between external terminals of the semiconductor power package 300, 500, 700, 800 and the drain D of the low side switches LS1, LS2, LSN. These terminals may be used as voltage sense terminals for external circuitry.

Semiconductor power packages 300, 500, 700, 800 as described herein may be of particular use in automotive engineering. By way of example, the semiconductor power packages 300, 500, 700, 800 may be configured to energize (e.g. BLDC) motors used in a fuel pump, water pump or in an electrically driven turbocharger.

Semiconductor power packages 300, 500, 700, 800 as described herein may provide an output power of, e.g., 1 W to 500 W, in particular of equal to or greater than or less than 10 W, 50 W, 200 W, 200 W, 300 W or 400 W. Semiconductor power packages 300, 500, 700, 800 as described herein may provide an output current of, e.g., 0.1 A to 100 A, in particular of equal to or greater than or less than 1 A, 10 A, 30 A, 50 A, 70 A or 90 A. During operation, voltages higher or less than 5V, 10V, 50V, 100V, 200V or 500V may be applied between the nodes 401 and 402. A switching frequency of the N-bridge may be in the range from 100 Hz to 100 MHz, but may also be outside of this range.

All semiconductor power packages 300, 500, 700, 800 provide for a space optimized package layout. Further, all semiconductor power packages 300, 500, 700, 800 provide for low stray impedance and reduce parasitic energy losses, superior distribution of external terminals along the periphery of the semiconductor power packages 300, 500, 700, 800 and allow for high heat removal capability.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor package comprising a multi-level arrangement, comprising:
an electrically conducting carrier having a mounting surface;
a first level first semiconductor power device having a first load electrode mounted over the mounting surface of the electrically conducting carrier and having a second load electrode opposite the first electrode;
a first level second semiconductor power device having a first load electrode mounted over the mounting surface of the electrically conducting carrier and having a second load electrode opposite the first electrode;
a first connection element having a first surface connected to the second load electrode of the first level first semiconductor power device and having a mounting surface opposite the first surface;
a second connection element having a first surface connected to the second load electrode of the first level second semiconductor power device and having a mounting surface opposite the first surface;
a second level first semiconductor power device having a first load electrode mounted over the mounting surface of the first connection element and having a second load electrode opposite the first electrode; and
a second level second semiconductor power device having a first load electrode mounted over the mounting surface of the second connection element and having a second load electrode opposite the first electrode.

2. The semiconductor package of claim 1, wherein the first load electrode of the first level first semiconductor power device and the first load electrode of the first level second semiconductor power device are source or emitter electrodes.

3. The semiconductor package of claim 1, wherein the first load electrode of the first level first semiconductor power device and the first load electrode of the first level second semiconductor power device are drain or collector electrodes.

4. The semiconductor package of claim 1, further comprising:
a connection element being electrically connected to the second load electrode of the second level first semiconductor power device and to the second load electrode of the second level second semiconductor power device.

5. The semiconductor package of claim 4, wherein the second level first semiconductor power device and the second level second semiconductor power device are arranged in a row, and wherein the connection element extends in a direction parallel to the direction of the row.

6. The semiconductor package of claim 4, wherein the second level first semiconductor power device and the second level second semiconductor power device are arranged in a row, and wherein the connection element extends in a direction perpendicular to the direction of the row.

7. The semiconductor package of claim 4, wherein the connection element is a clip.

8. The semiconductor package of claim 1, further comprising:
a first level third semiconductor power device having a first load electrode mounted over the mounting surface of the electrically conducting carrier and having a second load electrode opposite the first load electrode.

9. The semiconductor package of claim 8, further comprising:
a third connection element having a first surface connected to the second load electrode of the first level third semiconductor power device and having a mounting surface opposite the first surface.

10. The semiconductor package of claim 9, further comprising:
a second level third semiconductor power device having a first load electrode mounted over the mounting surface of the third connection element.

11. The semiconductor package of claim 1, wherein each semiconductor power device comprises a gate electrode which faces away from the electrically conducting carrier.

12. The semiconductor package of claim 1, further comprising:
first external terminals connected to the connection elements, wherein all first external terminals are arranged along a first peripheral side of the semiconductor package.

13. The semiconductor package of claim 12, further comprising:
one or more second external terminals connected to the load electrodes of the second level semiconductor power devices, wherein the one or more second external terminals are arranged along one or more second peripheral sides of the semiconductor package, wherein the one or more second peripheral sides are oriented perpendicular to the first peripheral side.

14. The semiconductor package of claim 12, wherein all gate electrodes are arranged along a third peripheral side of the semiconductor package, wherein the third peripheral side is opposite the first peripheral side.

15. A multi-phase bridge comprising:
an electrically conducing carrier;
a plurality of first level semiconductor power devices mounted over and electrically connected to the electrically conducting carrier;
a plurality of connection clips, wherein each connection clip is mounted over and electrically connected to one of the plurality of first level semiconductor power devices; and
a plurality of second level semiconductor power devices, wherein each second level semiconductor power device is mounted over one connection clip of the plurality of connection clips.

16. The multi-phase bridge of claim 15, wherein the each of the plurality of first level semiconductor power devices is mounted source-down or emitter-down on the electrically conducting carrier.

17. The multi-phase bridge of claim 15, wherein each of the plurality of second level semiconductor power devices is mounted source-down or emitter-down on the respective connection clip.

18. The multi-phase bridge of claim 15, further comprising:
a connection element mounted over and electrically connected to the plurality of second level semiconductor power devices.

19. The multi-phase bridge of claim 18, wherein the electrically conducing carrier is configured to be connected to an external ground potential and the common connection element is configured to be connected to an external power supply potential.

20. The multi-phase bridge of claim 15, wherein each of the plurality of first level semiconductor power devices is mounted drain-down or collector-down on the electrically conducting carrier.

21. The multi-phase bridge of claim 15, wherein each of the plurality of second level semiconductor power devices is mounted drain-down or collector-down on the respective connection element.

22. The multi-phase bridge of claim 15, further comprising a common connection element mounted over and electrically connected to the plurality of second level semiconductor power devices.

23. The multi-phase bridge of claim 22, wherein the plurality of second level semiconductor power devices are arranged in a row, and wherein the common connection element extends in a direction parallel to the direction of the row.

24. The multi-phase bridge of claim 22, wherein the plurality of second level semiconductor power devices are arranged in a row, and wherein the common connection element extends in a direction perpendicular to the direction of the row.

25. The multi-phase bridge of claim 15, further comprising:
a control semiconductor chip mounted over the electrically conducting carrier and configured to control gate electrodes of the first level semiconductor power devices and of the second level semiconductor power devices.
